(19) United States
(12) Patent Application Publication
(10) Pub. No.: US 2026/0060084 A1
(43) Pub. Date: Feb. 26, 2026

(54) SEMICONDUCTOR PACKAGE WITH ACTIVE THERMAL MANAGEMENT LID

(71) Applicant: Taiwan Semiconductor Manufacturing Company, Ltd., Hsinchu (TW)

(72) Inventors: Tzu Jung Tien, Hsinchu (TW); Jen-Yuan Chang, Hsinchu (TW)

(21) Appl. No.: 18/815,199

(22) Filed: Aug. 26, 2024

(51) Int. Cl. H01L 23/38; H01L 23/057; H01L 23/34; H01L 23/367; H01L 23/538; H01L 25/065

(52) U.S. Cl. CPC H01L 23/38; H01L 23/057; H01L 23/345; H01L 23/3675; H01L 25/0657; H01L 23/3672; H01L 23/538; H01L 2225/06513; H01L 2225/06517; H01L 2225/06541; H01L 2225/06565

(57) ABSTRACT

A semiconductor package includes a substrate with electrical conductors, one or more semiconductor dies disposed on the substrate and electrically connected with the electrical conductors of the substrate, and a lid disposed on the substrate. The one or more semiconductor dies are disposed in a space enclosed by the substrate and the lid. At least one thermoelectric device is at least partly embedded in the lid. The at least one thermoelectric device may be operated to cool the semiconductor package, or to heat the semiconductor package. A controller for the at least one thermoelectric device may be implemented in the one or more semiconductor dies.

### BACKGROUND

The following relates to semiconductor packages and packaging arts and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a side sectional view of a semiconductor package with an actively cooled lid.

FIG. 2 diagrammatically illustrates a top view of a semiconductor package with an actively cooled lid.

FIG. 3 diagrammatically illustrates a side sectional view of the semiconductor package of FIG. 1, including indicated dimensions.

FIG. 4 diagrammatically illustrates a side sectional view of a thermoelectric device according to an embodiment.

FIG. 5 diagrammatically illustrates a side sectional view of a thermoelectric device according to an embodiment.

FIG. 6 diagrammatically illustrates a side sectional view of a semiconductor package with an actively cooled lid according to another embodiment, which includes a heat sink disposed on the lid of the semiconductor package.

FIG. 7 diagrammatically illustrates a side sectional view of a semiconductor package with an actively cooled lid according to another embodiment.

FIG. 8 diagrammatically illustrates a side sectional view of a semiconductor package with a lid providing both active cooling and active heating.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package includes one or more semiconductor dies such as integrated circuit (IC) chips fabricated on and/or in silicon, which are disposed on a substrate. The one or more semiconductor dies may be directly attached to the substrate on which they are disposed, or may be arranged in a stack (e.g., with a lowermost semiconductor die directly attached to the substrate and one or more additional semiconductor dies attached to the lowermost semiconductor die). In another arrangement, the one or more semiconductor dies disposed on the substrate may be attached to an interposer, which in turn is attached to the substrate. The interposer may, for example, comprise a silicon wafer with through-vias. The substrate and/or the interposer (if included) may optionally include one or more redistribution layers (RDLs) to provide electrical routing of electrical signals and/or power to and/or from the one or more semiconductor dies. A lid is disposed over the one or more semiconductor dies to protect them, and the lid may be secured to or otherwise disposed on the substrate, e.g., a perimeter of the lid may be attached to the substrate, optionally in a sealed fashion to suppress ingress of water vapor or other contaminants.

Thermal management is a challenge in semiconductor packages. Some such packages include semiconductor dies that generate large quantities of heat. For example, advanced central processing unit (CPU) and graphical processing unit (GPU) packages for high performance computing (HPC) and artificial intelligence (AI) applications can output total chip power of around 400-600 watts or higher. A goal of some semiconductor package designs is to reduce the package footprint by close placement of multiple semiconductor dies (some or all of which may be high-power IC chips) within the lid, thus forming a concentrated high power heat source. Radiative and/or convective cooling can be provided by a heat sink disposed on top of the lid, and/or by heat transfer through the substrate. The thermal load that can be conveyed by these heat transfer pathways may be limited, however. Additionally, these heat transfer pathways are uncontrolled, and so are designed to ensure adequate cooling for “worst-case” situations in which the semiconductor package is generating maximum heat.

Another thermal management challenge is thermal transients. When a high-power semiconductor package is started up, or is transitioned from lower-power operation to higher-power operation, the package temperature rises. During this temperature transition, the semiconductor package may not be operating at an optimal (or design-basis) temperature, for example leading to reduced energy efficiency of the package.

Disclosed herein are semiconductor chip packages with improved thermal management. Various embodiments disclosed herein advantageously provide active cooling via one or more thermoelectric devices that are partially or fully embedded in the lid of the semiconductor package. This placement of the thermoelectric device or devices is advantageous because it operates to actively draw heat from the package toward the air (or other ambient) surrounding the semiconductor package.

In some such embodiments, the one or more semiconductor dies includes a power supply for operating the one or more thermoelectric devices. Electrical conductors embedded in (or in other embodiments, disposed on) the lid provide electrical connection from the power supply to the one or more thermoelectric devices partially or fully embedded in the lid. This advantageously provides a self-contained semiconductor package in which the one or more thermoelectric devices do not require a power input separate from that of the one or more semiconductor dies.

In some such embodiments, the lid may further include a temperature sensor that provides a temperature signal indicative of temperature of the semiconductor package. The cooling can be feedback controlled by the one or more semiconductor dies using this temperature sensor signal. Advantageously, this can enable active cooling provided by the one or more thermoelectric devices to be adjusted based on the operating temperature of the semiconductor package. Consequently, the active cooling is advantageously not overdesigned for the “worst case” situation, but rather provides active cooling in proportion to the operating temperature or other suitable metric.

In some embodiments, the one or more thermoelectric devices may also include at least one thermoelectric device at least partly embedded in a perimeter of the lid which is secured to the substrate. This provides active cooling at this junction, which may advantageously reduce thermal stress at the joinder between the lid perimeter and the substrate, thus improving reliability of the semiconductor package.

In a typical thermoelectric device operating on the Peltier effect, electric current flowing through the thermoelectric device in one direction causes heat transfer from one side of the thermoelectric device to an opposite side of the thermoelectric device. To provide thermoelectric cooling, the side from which heat is drawn is proximate to the one or more semiconductor dies, while the side to which heat is transferred is distal from the one or more semiconductor dies (so as to discharge that heat into the ambient, or into a heat sink if one is mounted on top of the lid). However, as recognized herein, by reversing the direction of the electric current the direction of heat flow produced by the thermoelectric device is also reversed. Hence, in some embodiments, the one or more semiconductor dies are configured to reverse the direction of the electric current supplied to the one or more thermoelectric devices to switch between cooling and heating. Thus, for example, the one or more thermoelectric devices advantageously can initially provide active heating to rapidly ramp the semiconductor package up to its design-basis operating temperature. Thereafter, the one or more thermoelectric devices can be switched to provide active cooling to maintain the semiconductor package at its design-basis operating temperature. The aforementioned temperature sensor can provide the input for the one or more semiconductor dies to determine when to switch the direction of the electrical current to switch from heating to cooling.

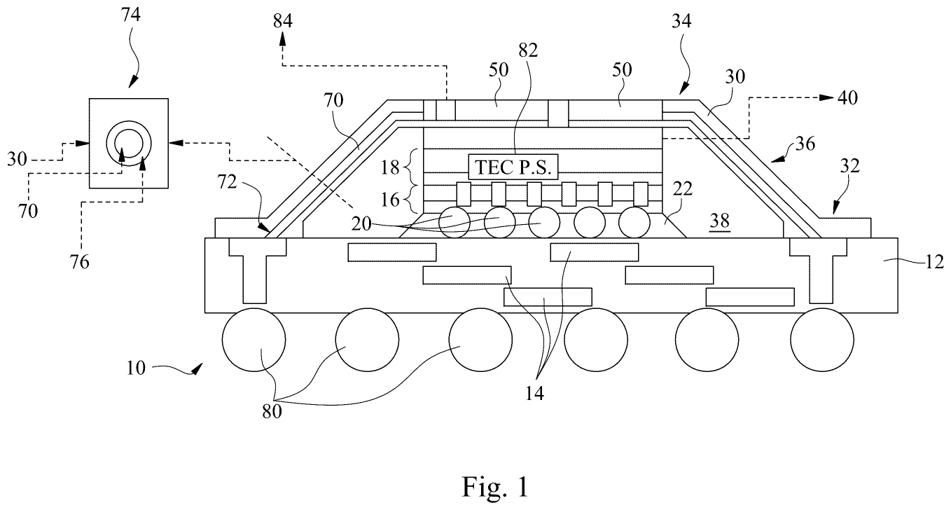

With reference now to FIG. 1, a side sectional view of a semiconductor package 10 with an actively cooled lid is diagrammatically illustrated. The semiconductor package 10 includes a substrate 12 including electrical conductors 14, and one or more semiconductor dies 16, 18 disposed on the substrate and electrically connected with the electrical conductors 14 of the substrate 12. The substrate 12 can be of various types. In some embodiments, the substrate 12 may be a silicon wafer having through-silicon vias (TSVs) and a redistribution layer (RDL) on one or both sides providing the conductors 14 (details not shown). In other embodiments, the substrate 12 may comprise a resin material hosting a matrix of copper foil layers interconnected by vias forming the conductors 14 (details not shown). These are merely some nonlimiting illustrative examples of suitable embodiments of the substrate 12 with conductors 14.

In the illustrative example, the one or more semiconductor dies 16, 18 include a bottom semiconductor die 16 and a top semiconductor die 18 arranged as a stack. The bottom semiconductor die 16 is attached to the substrate 12 by electrically conductive bonds 20 such as a microarray of bonding bumps, ball grid array (BGA), or so forth. An underfill material 22 of an electrically insulating material such as an epoxy (by way of nonlimiting illustrative example) fills the space between the bottom semiconductor die 16 and the substrate 12 between the conductive bonds 20. The underfill material 22 provides improved structural robustness and/or contributes to thermal heat transfer from the bottom semiconductor die 16 to the substrate 12. The electrically conductive bonds 20 also provide electrical connections between the bottom semiconductor die 16 and the conductors 14 of the substrate 12. The top semiconductor die 18 is attached to the bottom semiconductor die 16 forming a stack of two semiconductor dies. The attachment of the top semiconductor die 18 to the bottom semiconductor die 16 may be by way of TSVs of a silicon substrate of the bottom semiconductor die 16 and a microarray of bonding bumps or so forth. While two semiconductor dies 16 and 18 are shown as a stack in the example of FIG. 1, it will be appreciated that such a stack can be extended to three (or more) semiconductor dies. Moreover, other arrangements of two or more semiconductor dies can be employed, such as (by way of some further nonlimiting examples, not shown): having all semiconductor dies directly attached to the substrate 12 via electrically conductive bonds and with optional underfill material; or, employing a silicon interposer with TSVs and having the semiconductor dies mounted on the interposer which in turn is mounted on the substrate 12 (with TSVs of the interposer providing electrical connection between the semiconductor dies and the electrical conductors 14 of the substrate 12); various combinations thereof, and/or so forth. Moreover, in further embodiments it is contemplated for the one or more semiconductor dies to consist of a single semiconductor die, which may be directly attached to the substrate 12 or may have a silicon interposer disposed between the single semiconductor die and the substrate 12.

In general, the one or more semiconductor dies 16, 18 can be any type of integrated circuit (IC) die. By way of some nonlimiting examples, each semiconductor die may be: a system-on-integrated chip (SoIC); a central processing unit (CPU); a graphical processing unit (GPU); a DRAM or other electronic memory die; a semiconductor die on which analog circuitry is fabricated, e.g. for analog radio frequency (RF) signal processing; various combinations thereof, and/or so forth. A single semiconductor die may include two or more of these functional components monolithically fabricated on a single semiconductor wafer such as a single silicon wafer, single gallium arsenide (GaAs) wafer, or so forth. Again, there are merely some nonlimiting illustrative examples.

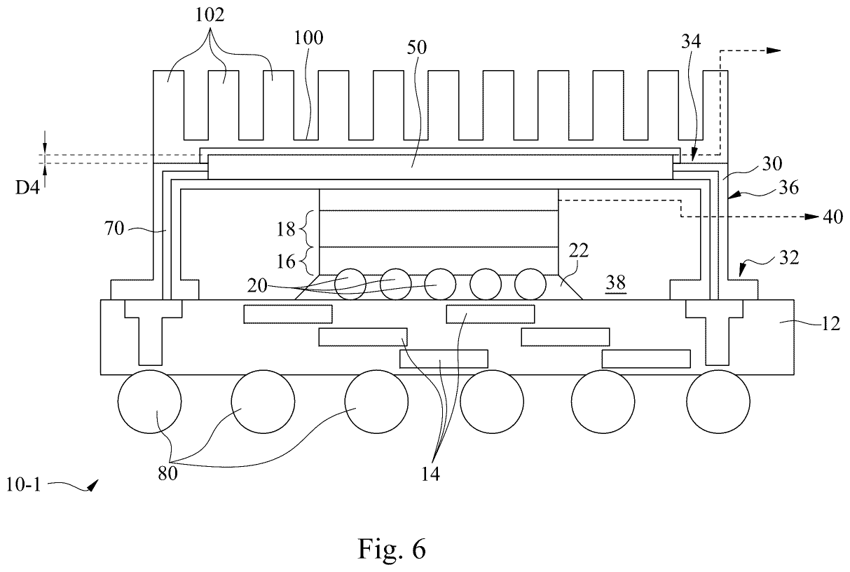

The semiconductor package 10 of FIG. 1 further includes a lid 30 disposed on the substrate 12. In the illustrative example, the lid 30 has a perimeter 32 that is secured to the substrate 12. The illustrative lid 30 has a top 34 which is distal from the substrate 12, and a sidewall 36 extending from the top 34 to the perimeter 32 of the lid 30. In the illustrative example of FIG. 1 the sidewall 36 is slanted; however, the sidewall may have a different geometry, such as a vertical sidewall in the example of FIG. 6. The one or more semiconductor dies 16, 18 are disposed in a space 38 enclosed by the substrate 12 and the lid 30. In some embodiments, the space 38 is filled with air, although in other embodiments the space 38 may be filled with heat dissipation glue or another thermally conductive material. The top semiconductor die 18 (or, by extension, the one or more semiconductor dies 16, 18) is in thermally conductive contact with the lid 30, and more particularly is in thermally conductive contact with the top 34 of the lid 30 in the example of FIG. 1. To this end, the top semiconductor die 18 optionally includes a backside metallization 40 to enhance this thermal contact. The lid 30 may comprise a metal such as steel, or iron, nickel, chromium, tin, zinc, or an alloy of two or more of these; or may comprise a nonmetal such as a carbon reinforced polymer, glass, ceramic, or so forth. The bonding of the perimeter 32 of the lid 30 to the substrate 12 may employ any suitable adhesive for bonding between the material of the lid 30 and the material of the substrate 12.

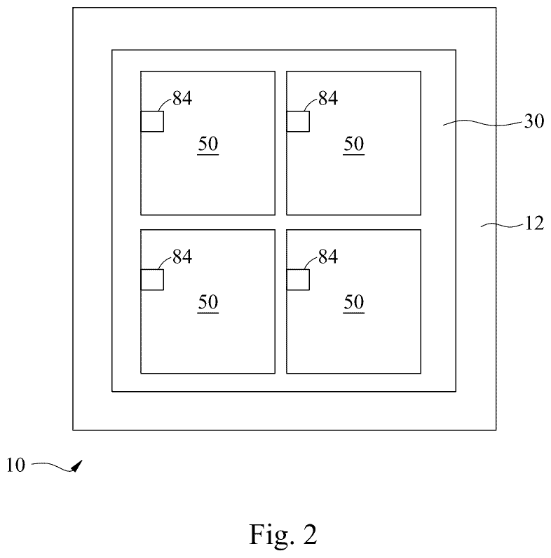

With continuing reference to FIG. 1 and with further reference to FIG. 2 which diagrammatically illustrates a top view of a semiconductor package 10, the semiconductor package 10 further includes at least one thermoelectric device 50 which is thermally coupled with the lid 30, in the illustrative example by being at least partly embedded in the lid 30. In the illustrative example of FIGS. 1 and 2, four thermoelectric devices 50 are at least partially embedded in the lid 30, as seen in the top view of FIG. 2. (The side sectional view of FIG. 1 shows two of the four thermoelectric devices 50 in side view. In the example of FIGS. 1 and 2, the four thermoelectric devices 50 are arranged in a 2×2 array as seen in FIG. 2, at least partially embedded in the top 34 of the lid 30. More generally, the number of thermoelectric devices 50 can be one (i.e., a single thermoelectric device 50), two, three, four (as illustrated), five, six, or more; and if there are more than one thermoelectric device 50 then they can be variously arranged (the 2×2 array of FIG. 2 being merely one nonlimiting illustrative example).

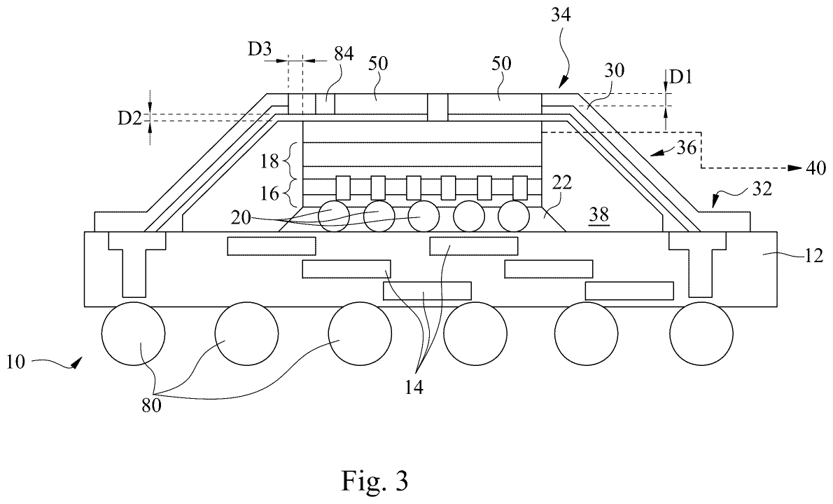

With reference now to FIG. 3, which again shows the side view of the semiconductor package 10 of FIG. 1, but in FIG. 3 with dimensions D1, D2, and D3 indicated, various embodiments of the at least partial embedment of the at least one thermoelectric device 50 in the lid 30 are described. By “at least partially embedded”, it is meant that the thermoelectric devices may be fully embedded in the lid 30 by being entirely surrounded by the material of the lid 30, or may be disposed in a recess of the lid 30 (providing partial embedding in the lid 30). More generally, the thermoelectric device may be thermally coupled with the lid. The dimensions D1 and D2 can be used to quantify the partial or full embedding of the one or more thermoelectric devices 50 in the lid 30.

Dimension D1 is the height of the surface of (the top 34 of) the lid 30 to the top surface of the one or more thermoelectric devices 50. In general, D1 can be positive, negative, or zero.

In some embodiments, D1 is positive, in which case the upper surface of (the top 34 of) the lid 30 is higher than the top surface of the one or more thermoelectric devices 50. In this case, the lid 30 coats the top surface of the one or more thermoelectric devices 50. Having D1 be positive advantageously allows for the material of the lid 30 coating the top surface of the one or more thermoelectric devices 50 to protect the one or more thermoelectric devices 50.

In some embodiments, D1 is negative, in which case the upper surface of (the top 34 of) the lid 30 is lower than the top surface of the one or more thermoelectric devices 50. In this case, an upper portion of the one or more thermoelectric devices 50 protrude upward from the top surface of (the top 34 of) the lid 30, and the top surface of the one or more thermoelectric devices 50 is not coated with the material of the lid 30. This arrangement can be advantageous if a heat sink is disposed on the lid, as the protruding upper portion of the one or more thermoelectric devices 50 can reside in a recess of the heat sink (see example of FIG. 6).

In some embodiments, D1 is zero, in which case the upper surface of (the top 34 of) the lid 30 is at the same height (e.g., coplanar with) the top surface of the one or more thermoelectric devices 50.

Dimension D2 indicated in FIG. 3 is the height (or separation) of the lower surface of (the bottom 34 of) the lid 30 to the bottom surface of the one or more thermoelectric devices 50. In general, D2 can be positive, negative, or zero.

In some embodiments, D2 is positive, in which case the lower surface of (the top 34 of) the lid 30 is lower than the bottom surface of the one or more thermoelectric devices 50. In this case, the lid 30 coats the bottom surface of the one or more thermoelectric devices 50. Having D2 be positive advantageously allows for the material of the lid 30 coating the bottom surface of the one or more thermoelectric devices 50 to protect the one or more thermoelectric devices 50.

In some embodiments, D2 is negative, in which case the lower surface of (the top 34 of) the lid 30 is higher than the lower surface of the one or more thermoelectric devices 50. In this case, a lower portion of the one or more thermoelectric devices 50 protrude downward from the bottom surface of (the top 34 of) the lid 30, and the bottom surface of the one or more thermoelectric devices 50 is not coated with the material of the lid 30. This arrangement can be advantageous insofar as it can facilitate direct thermal contact between the one or more semiconductor dies 16, 18 and the one or more thermoelectric devices 50 (e.g., the backside metallization 40 of the top semiconductor die 18 can directly contact the bottom surface of the one or more thermoelectric devices 50).

In some embodiments, D2 is zero, in which case the lower surface of (the top 34 of) the lid 30 is at the same height (e.g., coplanar with) the bottom surface of the one or more thermoelectric devices 50.

With continuing reference to FIG. 3, dimension D3 is the distance from the periphery of the one or more thermoelectric devices 50 to the periphery of the one or more semiconductor dies 16, 18 being cooled by the one or more thermoelectric devices 50. In general, D3 can be positive, negative, or zero. To maximize the cooling effectiveness, particularly in the vicinity of the periphery of the one or more semiconductor dies 16, 18, it is beneficial for D3 to be positive, so that the periphery of the one or more thermoelectric devices 50 extends beyond the periphery of the one or more semiconductor dies 16, 18 being cooled by the one or more thermoelectric devices 50.

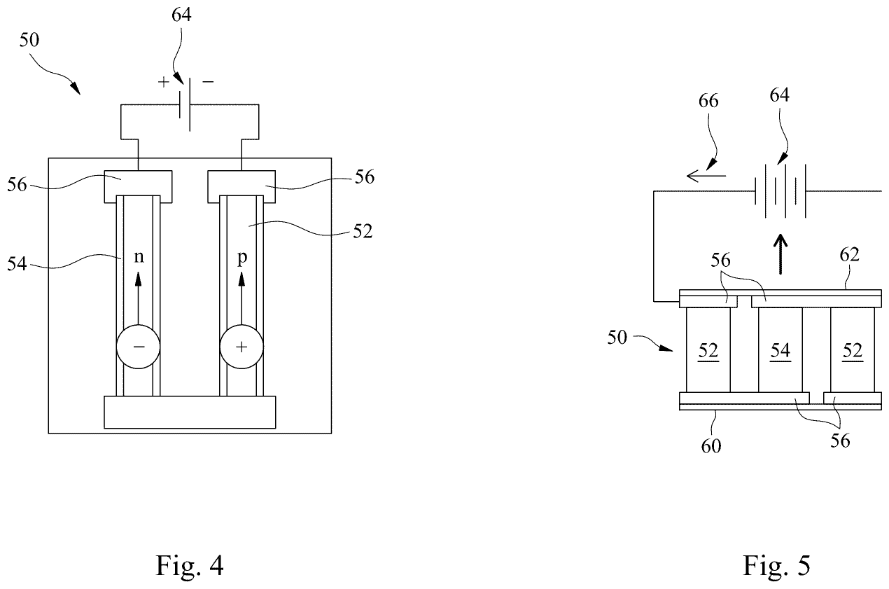

With reference now to FIGS. 4 and 5, side sectional views are shown of one of the one or more thermoelectric devices 50. The illustrative thermoelectric device 50 operates on the Peltier effect, and includes regions 52 which are doped p-type (i.e., p-type regions 52) and regions 54 which are doped n-type (i.e., n-type regions 54), which are electrically interconnected in series by electrical conductors 56. As seen in the example of FIG. 5, a first plate 60 and a second plate 62, which may be thermally conductive plates (e.g., thermally conductive but electrically insulating ceramic plates or the like) disposed at opposite ends of the p-type and n-type regions 52 and 54. A DC voltage source 64 applies a voltage (indicated in FIG. 4) across the series-interconnected p-type and n-type regions 52 and 54, producing an electric current 66 (indicated in FIG. 5) through the series-interconnected p-type and n-type regions 52 and 54. As diagrammatically indicated in FIG. 4, this produces hole transport in the p-type regions 52 and electron transport in the n-type regions 54, with both the holes and electrons moving away from the first plate 60 and toward the second plate 62. The hole and electron transport thus operates by the Peltier effect to actively transport heat from the first plate 60 to the second plate 62. Thus, the thermoelectric device 50 in this configuration acts as a thermoelectric cooler (TEC) for cooling a mass in thermal contact with the first plate 60 by expelling heat from that first mass to the second plate 62.

It is noted that for simplicity FIGS. 4 and 5 illustrate only two or three of the interconnected p-type and n-type regions 52 and 54. However, each thermoelectric device 50 may include a number of interconnected p-type and n-type regions 52 and 54, which may optionally be arranged in a two-dimensional array or the like to provide cooling over a corresponding two-dimensional area.

With reference back to FIG. 1, the mass being cooled comprises the one or more semiconductor dies 16, 18 which are in thermal contact with the first plate 60 of the thermoelectric device 50 (e.g., the backside metallization 40 of the top semiconductor die 18) to the second plate 62 which is the top surface of the at least one thermoelectric device 50. To provide electrical power to the one or more thermoelectric devices 50, lid conductors 70 are disposed on and/or embedded in the lid 30, and are connected with the electrical conductors 14 of the substrate 12. In the illustrative example of FIG. 1, the lid conductors 70 are embedded in the lid 30, and pass through the sidewall 36 of the lid 30 to the perimeter 32 of the lid, where ends 72 of the lid conductors 70 disposed at the perimeter 32 of the lid 30 connect with the electrical conductors 14 of the substrate 12. As diagrammatically shown by a cross-sectional view 74 included in FIG. 1, the lid conductors 70 are surrounded by an electrically insulating sheath 76 to electrically isolate the embedded lid conductors 70 from the lid 30 within which they are embedded. If the lid 30 is made of an electrically insulating material, then it is contemplated to omit the electrically insulating sheath 76. Instead of the illustrated embedded lid conductors 70, it is contemplated for the lid conductors to be disposed on the lid, e.g., running along an inside surface of the lid, or for the lid conductors to pass through the space 38.

With continuing reference to FIG. 1, the semiconductor package 10 is configured to be electrically and mechanically attached to a substrate, such as a printed circuit board (PCB) or the like, by way of electrically conductive bonds 80 such as a ball grid array (BGA) or so forth. The electrically conductive bonds 80 may be solder bumps, copper balls (optionally with solder coating), or so forth. In operation, power and/or electrical signals are conveyed to and from the semiconductor package 10 via the electrical conductors 14 of the substrate 12 and the electrically conductive bonds 80.

In some embodiments, power for operating the one or more thermoelectric devices 50 at least partially embedded in the lid 30 may be supplied externally from the semiconductor package 10. Put another way, the voltage source 64 (see FIG. 4) may be located outside of the semiconductor package 10 and operatively connected with the one or more thermoelectric devices 50 by way of the electrically conductive bonds 80 and the electrical conductors 14 of the substrate 12 and the lid conductors 70. For example, if the semiconductor package 10 is mounted on a printed circuit board, then this may deliver the power for operating the one or more thermoelectric devices 50.

In other embodiments, the power for operating the one or more thermoelectric devices 50 is provided by the one or more semiconductor dies 16, 18. This is diagrammatically shown in FIG. 1 by way of a thermoelectric cooler (TEC) power supply (P.S.) 82 implemented in the top semiconductor die 18. Put another way, the voltage source 64 (see FIG. 4) may be integrated with, and implemented by, the one or more semiconductor dies 16, 18. In this approach, the one or more semiconductor dies 16, 18 are configured to output the electric current 66 (see FIG. 5) to the at least one thermoelectric device 50 via an electrical path including the electrical conductors 14 of the substrate 12 and the lid conductors 70.

In some embodiments, this power is supplied in an open-loop fashion, i.e., the thermoelectric cooler power supply 82 outputs a constant current (or constant voltage) with no feedback control.

In other embodiments, the thermoelectric cooler power supply 82 is a controller 82 that is configured (e.g., programmed using digital logic of the one or more semiconductor dies 16, 18) to perform feedback-controlled active cooling of the semiconductor package 10 using the at least one thermoelectric device 50 and feedback received from at least one temperature sensor 84. Put another way, the one or more semiconductor dies 16, 18 are configured to control the output electric current to perform active cooling of the semiconductor package 10 using the at least one thermoelectric device 50. In the illustrative embodiment, the at least one temperature sensor 84 is integrated into the lid 30, and optionally into the at least one thermoelectric device 50, and is read via the lid conductors 70. FIG. 1 illustrates an example in which there is a single temperature sensor 84, while the top view of FIG. 2 illustrates an example in which there are multiple temperature sensors 84, illustrative four temperature sensors 84 with one located proximate to each of the four respective thermoelectric devices 50. The controller 82 can implement any suitable feedback controller, such as a proportional-integral (PI) feedback controller, a proportional-integral-derivative (PID) feedback controller, or so forth. In a typical approach, the controller 82 is programmed to maintain the semiconductor package 10 at no higher than a predefined setpoint temperature (as measured at the temperature sensor 84), and hence increases the current 66 as the temperature measured by the temperature sensor 84 increases above the setpoint. The current 66 may be kept at zero as long as the temperature is below the setpoint. This is merely one nonlimiting illustrative control paradigm.

The semiconductor package 10 of FIGS. 1-3 does not include a heat sink, and has slanted sidewalls 36.

With reference to FIG. 6, a variant semiconductor package 10-1 is similar to the semiconductor package of FIGS. 1-3, and includes the substrate 12 and conductors 14, at least one semiconductor die 16, 18, bonding bumps 20, and underfill 22, as previously described. The semiconductor package 10-1 has a modified lid 36 with a top 34 as previously described, but with vertical sidewalls 36 through which the embedded lid conductors 70 pass to the lid perimeter 32. Furthermore, the semiconductor package 10-1 includes a heat sink 100 disposed on the lid 30, and more particularly on the top 34 of the lid 30, so that the heat sink 100 is in thermal contact with the one or more thermoelectric devices 50. The heat sink 100 includes heat dissipation fins 102 extending upward, i.e., away from the semiconductor package 10-1. In the illustrative example of FIG. 6, an upper portion of the one or more thermoelectric devices 50 protrude upward from the top surface of (the top 34 of) the lid 30 (corresponding to D1 being negative, in the notation previously described with reference to FIG. 3), and the heat sink 100 has a recess in its lower surface that receives the protruding upper portion of the one or more thermoelectric devices 50 so that the one or more thermoelectric devices 50 are also partially embedded in the lower portion of the heat sink 100. The one or more thermoelectric devices 50 thus advantageously operate synergistically with the heat sink 100 to efficiently cool the semiconductor package 100-1.

In the embodiments of FIGS. 1-3 and FIG. 6, the one or more thermoelectric devices 50 are at least partially embedded in the top 34 of the lid 30.

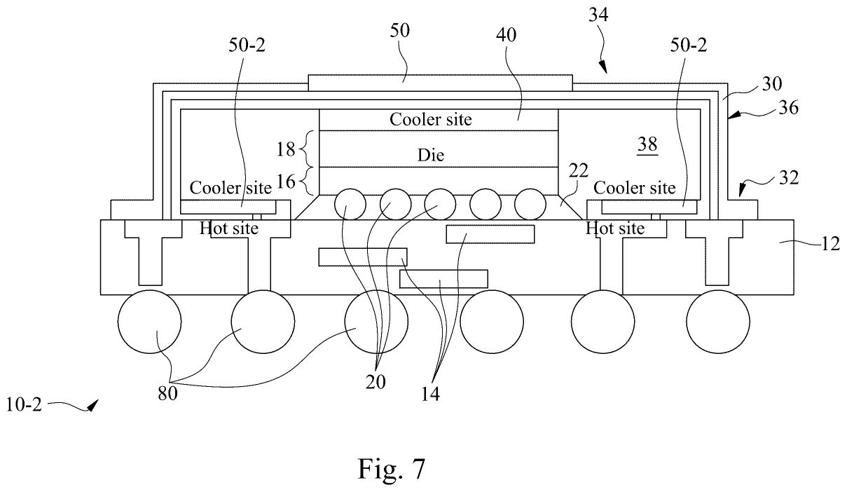

With reference to FIG. 7, another variant semiconductor package 10-2 is similar to the semiconductor package of FIGS. 1-3, and includes the substrate 12 and conductors 14, at least one semiconductor die 16, 18, bonding bumps 20, and underfill 22, as previously described. The semiconductor package 10-1 has a modified lid 36 with a top 34 as previously described, but with vertical sidewalls 36 through which the embedded lid conductors 70 pass to the lid perimeter 32, similar to the embodiment of FIG. 6. The embodiment of FIG. 7 does not include a heat sink (although it could include a heat sink, as could the embodiment of FIGS. 1-3). The semiconductor package 10-2 includes the one or more thermoelectric devices 50 at least partially embedded in the top 34 of the lid 30, as in the previous embodiments; however, the semiconductor package 10-2 further includes one or more (illustrative two) thermoelectric devices 50-2 at least partially embedded in the perimeter 32 of the lid 30 which is secured to the substrate 12. This provides active cooling at the junction between the perimeter 32 of the lid 30 and the substrate 12, which may advantageously reduce thermal stress at the joinder between the lid perimeter 32 and the substrate 12, thus improving reliability of the semiconductor package 10-2 (and particularly, reliability of the adhesion or other joinder between the lid perimeter 32 and the substrate 12.

In the foregoing embodiments, the one or more thermoelectric devices 50 have been used to cool the semiconductor package 10 or 10-1 or 10-2.

However, as recognized herein and with reference back to FIGS. 4 and 5, these same one or more thermoelectric devices 50 can also operate to heat the semiconductor package. This can be done by reversing the direction of the electric current 66 flowed through the one or more thermoelectric devices 50, so that the holes and electrons flow in the opposite direction to cause heat transfer from the second plate 62 to the first plate 60. As further recognized herein, it can be beneficial to operate the one or more thermoelectric devices 50 in such a heating mode, for example to reduce the transition time to an elevated operating temperature when the semiconductor package starts operating, or is switched from a low operational load to a higher operational load.

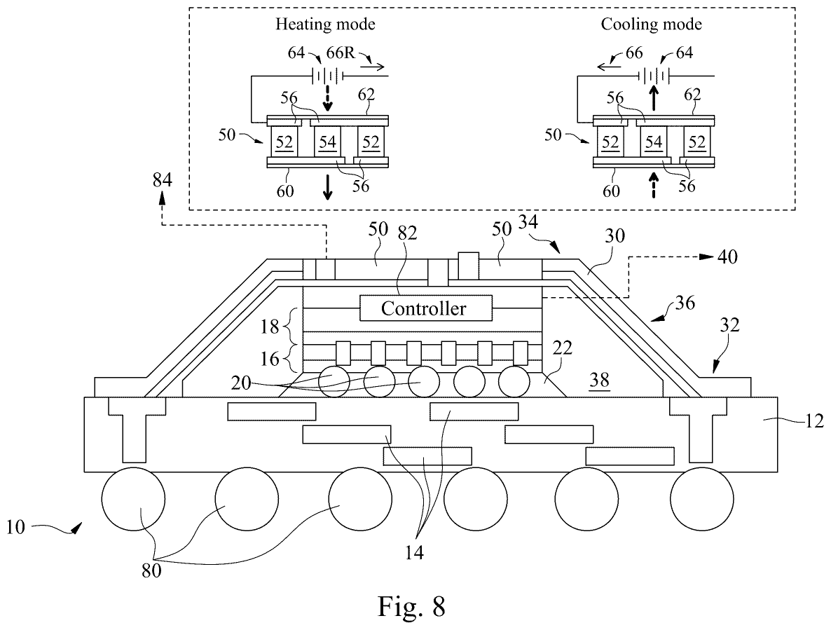

With reference to FIG. 8, the semiconductor package 10 of FIGS. 1-3 is again shown in the same side sectional view previously depicted in FIGS. 1 and 3, and including the on-board circuit 82 for operating the one or more thermoelectric devices 50. In the embodiment of FIG. 8, the circuit 82 is specifically a controller 82. Superimposed above the side sectional view in FIG. 8 are diagrammatic representations of the one or more thermoelectric devices 50 as previously shown in FIG. 5. A right-hand diagram shows the “Cooling mode”, with the one or more thermoelectric devices 50 operating in cooling mode as previously described with reference to FIG. 5, and with the current 66 flowing as indicated. A left-hand diagram shows the “Heating mode”, with the one or more thermoelectric devices 50 operating in a heating mode by reversing the polarity of the applied voltage 64 and thus applying a current 66R with a reversed direction. The controller 82 suitably switches from the cooling mode to the heating mode by reversing a direction of the electric current between current 66 (for cooling) and reversed current 66R (for heating). The switching is suitably based on the temperature signal transmitted from the temperature sensor 84 to the one or more semiconductor dies 16, 18 which implement the controller 82.

In the following, some further embodiments are described.

In a nonlimiting illustrative embodiment, a semiconductor package comprises: a substrate including electrical conductors; one or more semiconductor dies disposed on the substrate and electrically connected with the electrical conductors of the substrate; a lid disposed on the substrate, the one or more semiconductor dies being disposed in a space enclosed by the substrate and the lid; and at least one thermoelectric device at least partly embedded in the lid.

In a nonlimiting illustrative embodiment, a method of operating a semiconductor package which includes one or more semiconductor dies disposed on a substrate and a lid disposed over the one or more semiconductor dies and secured to the substrate is disclosed. The method comprises: acquiring a temperature signal indicative of a temperature of the semiconductor package using a temperature sensor; transmitting the temperature signal to the one or more semiconductor dies; and cooling the semiconductor package by outputting an electric current from the one or more semiconductor dies to operate at least one thermoelectric device at least partially embedded in the lid.

In a nonlimiting illustrative embodiment, a semiconductor package comprises: a substrate; one or more semiconductor dies disposed on the substrate; a lid, the one or more semiconductor dies being disposed in a space enclosed by the substrate and the lid; and at least one thermoelectric device at least partly embedded in the lid.

In a nonlimiting illustrative embodiment, a semiconductor package includes a substrate with electrical conductors, one or more semiconductor dies disposed on the substrate and electrically connected with the electrical conductors of the substrate, and a lid disposed on the substrate. The one or more semiconductor dies are disposed in a space enclosed by the substrate and the lid. At least one thermoelectric device is at least partly embedded in the lid. The at least one thermoelectric device may be operated to cool the semiconductor package, or to heat the semiconductor package. A controller for the at least one thermoelectric device may be implemented in the one or more semiconductor dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a substrate including electrical conductors;
one or more semiconductor dies disposed on the substrate and electrically connected with the electrical conductors of the substrate;
a lid disposed on the substrate, the one or more semiconductor dies being disposed in a space enclosed by the substrate and the lid; and
at least one thermoelectric device at least partly embedded in the lid.

2. The semiconductor package of claim 1, further comprising:
lid conductors disposed on and/or embedded in the lid and connected with the electrical conductors of the substrate.

3. The semiconductor package of claim 2, wherein the one or more semiconductor dies are configured to output an electric current to the at least one thermoelectric device via an electrical path including the electrical conductors of the substrate and the lid conductors.

4. The semiconductor package of claim 3, wherein the one or more semiconductor dies are further configured to control the output electric current to perform active cooling of the semiconductor package using the at least one thermoelectric device.

5. The semiconductor package of claim 4, further comprising:
at least one temperature sensor, wherein the one or more semiconductor dies are configured to perform feedback-controlled active cooling of the semiconductor package using the at least one thermoelectric device and feedback received from the at least one temperature sensor.

6. The semiconductor package of claim 5, wherein the at least one temperature sensor is disposed on or embedded in the lid.

7. The semiconductor package of claim 4, wherein the one or more semiconductor dies are further configured to reverse a direction of the output electric current to perform active heating of the semiconductor package using the at least one thermoelectric device.

8. The semiconductor package of claim 2, wherein:
the lid conductors are embedded in the lid and pass through a sidewall of the lid to a perimeter of the lid, and
ends of the lid conductors disposed at the perimeter of the lid connect with the electrical conductors of the substrate.

9. The semiconductor package of claim 1, wherein the at least one thermoelectric device includes at least one thermoelectric device at least partly embedded in a top of the lid, wherein the top of the lid is distal from the substrate.

10. The semiconductor package of claim 9, wherein the at least one thermoelectric device further includes at least one thermoelectric device at least partly embedded in a perimeter of the lid which is secured to the substrate.

11. The semiconductor package of claim 1, wherein the at least one thermoelectric device includes at least one thermoelectric device completely embedded in a top of the lid, wherein the top of the lid is distal from the substrate.

12. The semiconductor package of claim 1, further comprising:
a heat sink including fins, the heat sink disposed on a top of the lid distal from the substrate with the fins extending away from the top of the lid.

13. The semiconductor package of claim 12, wherein the at least one thermoelectric device includes at least one thermoelectric device partially disposed in a recess of the top of the lid and partially disposed in a recess of the heat sink.

14. A method of operating a semiconductor package including one or more semiconductor dies disposed on a substrate and a lid disposed over the one or more semiconductor dies and secured to the substrate, the method comprising:
acquiring a temperature signal indicative of a temperature of the semiconductor package using a temperature sensor;
transmitting the temperature signal to the one or more semiconductor dies; and
cooling the semiconductor package by outputting an electric current from the one or more semiconductor dies to operate at least one thermoelectric device at least partially embedded in the lid.

15. The method of claim 14, wherein the cooling includes performing feedback control by the one or more semiconductor dies of the output electric current based on the temperature signal transmitted to the one or more semiconductor dies.

16. The method of claim 14, further comprising:
switching from the cooling to heating the semiconductor package by reversing a direction of the electric current, the switching being based on the temperature signal transmitted to the one or more semiconductor dies.

17. A semiconductor package comprising:
a substrate;
one or more semiconductor dies disposed on the substrate;
a lid, the one or more semiconductor dies being disposed in a space enclosed by the substrate and the lid; and
at least one thermoelectric device thermally coupled with the lid.

18. The semiconductor package of claim 17, further comprising:
electrical conductors connecting the one or more semiconductor dies to the at least one thermoelectric device;
wherein the one or more semiconductor dies are configured to power the at least one thermoelectric device via the electrical conductors to cool the semiconductor package.

19. The semiconductor package of claim 18, further comprising:
a temperature sensor disposed on or embedded in the lid;
wherein the one or more semiconductor dies are configured to control the powering of the at least one thermoelectric device via the electrical conductors to cool the semiconductor package based on a temperature signal output by the temperature sensor.

20. The semiconductor package of claim 17, further comprising:
electrical conductors connecting the one or more semiconductor dies to the at least one thermoelectric device;
wherein the one or more semiconductor dies are configured to power the at least one thermoelectric device via the electrical conductors to heat the semiconductor package.
